(19) United States
(12) Patent Application Publication
(10) Pub. No.: US 2026/0114333 A1
(43) Pub. Date: Apr. 23, 2026

(54) SEMICONDUCTOR PACKAGE STRUCTURE AND METHOD OF MANUFACTURING THE SAME

(71) Applicant: NANYA TECHNOLOGY CORPORATION, New Taipei City (TW)

(72) Inventors: Wu-Der YANG, New Taipei City (TW); Chun-Huang YU, New Taipei City (TW)

(21) Appl. No.: 18/918,849

(22) Filed: Oct. 17, 2024

(51) Int. Cl. H01L 23/498; H01L 21/48; H01L 23/00; H01L 23/13; H01L 23/31

(52) U.S. Cl. CPC H10W 90/401; H10W 70/05; H10W 70/68; H10W 72/50; H10W 74/111; H10W 90/701

(57) ABSTRACT

A label dispensing device includes a housing having a label outlet, a collection reel, a feeding reel, a driving mechanism and a peeling mechanism. The collection reel and the feeding reel are rotatably disposed in the housing. The driving mechanism drives one of the feeding reel and the collection reel for conveying a label strip from the feeding reel to the collection reel. The peeling mechanism is disposed in the housing and used to change a conveying direction of the label strip being pulled from the feeding reel towards the label outlet into a recycled direction intersected with the conveying direction from the peeling mechanism downwardly for peeling off one of label stickers from the label strip when the label sticker is passing the peeling mechanism.

### BACKGROUND

### Field of Invention

The present disclosure relates to a semiconductor package structure. More particularly, the present disclosure relates to a flip-chip typed semiconductor package structure and a method of manufacturing the same.

### Description of Related Art

Generally, in the package design of DRAM, a flip-chip type package might be provided in order to improve power delivery to meet high-speed requirements.

However, when wirings of signal/power/ground are densely distributed inside the substrate of the flip-chip type package, due to interference from those neighbored signal wirings, the speed and conduction performance of power and ground still might be affected and weakened, and IR drop effect might be caused in the flip-chip type package.

Thus, the above-mentioned technology obviously still has inconveniences and defects, which are issues that the industry needs to solve urgently.

### SUMMARY

One aspect of the present disclosure is to provide a semiconductor package structure and a method of manufacturing the same for solving the difficulties mentioned above in the prior art.

In one embodiment of the present disclosure, a semiconductor package structure includes a substrate, a semiconductor die and an encapsulated body. The substrate includes a main layer, a breach portion penetrated through the main layer, a spanning portion extending across the breach portion from the main layer, at least one power solder ball mounted on the main layer, at least one ground solder ball mounted on the main layer, at least one power wiring embedded inside the spanning portion and the main layer, and at least one ground wiring embedded inside the spanning portion and the main layer. The semiconductor die is mounted on the substrate, and provided with at least one power contact pad and at least one ground contact pad extended into the breach portion, respectively. The power contact pad is electrically connected to the power wiring with a power bonding wire via the breach portion, and the ground contact pad is electrically connected to the ground wiring with a ground bonding wire via the breach portion. The encapsulated body encloses the substrate and the semiconductor die together.

According to one or more embodiments of the present disclosure, in the semiconductor package structure, the main layer is provided with a front surface and a rear surface which are opposite to each other, the power solder ball and the ground solder ball are located on the front surface of the main layer, and the semiconductor die fixedly covers the rear surface of the main layer, the breach portion and the spanning portion.

According to one or more embodiments of the present disclosure, in the semiconductor package structure, the substrate includes at least one signal solder ball mounted on the main layer, and at least one signal wiring embedded inside the main layer only. The semiconductor die is further provided with at least one signal contact pad extended within the breach portion, and the signal contact pad is electrically connected to the signal wiring with a signal bonding wire via the breach portion.

According to one or more embodiments of the present disclosure, in the semiconductor package structure, the spanning portion is connected to opposite edges of the breach portion, respectively.

According to one or more embodiments of the present disclosure, in the semiconductor package structure, the spanning portion is in one of a linear shape and a cross shape.

According to one or more embodiments of the present disclosure, in the semiconductor package structure, the spanning portion includes a first long portion and a second long portion which are orthogonal to each other. The power solder ball includes a plurality of power solder balls, one part of the power wirings extends into the first long portion through the second long portion, and another part of the power wirings extends into the first long portion without passing through the second long portion, the ground solder ball includes a plurality of ground solder balls, one part of the ground wirings extends into the first long portion through the second long portion, and another part of the ground wirings extends into the first long portion without passing through the second long portion.

According to one or more embodiments of the present disclosure, in the semiconductor package structure, one part of the encapsulated body covers a front surface of the main layer, the breach portion and the spanning portion, and another part of the encapsulated body covers a rear surface of the main layer and the semiconductor die.

According to one or more embodiments of the present disclosure, in the semiconductor package structure, the spanning portion separates the breach portion into at least two windows, and the power contact pad and the ground contact pad are respectively extended within the windows.

According to one or more embodiments of the present disclosure, in the semiconductor package structure, the spanning portion is provided without any signal wiring embedded therein.

According to one or more embodiments of the present disclosure, in the semiconductor package structure, the power wiring includes a first power finger mounted on the main layer, a second power finger mounted on the spanning portion, and a power conductive trace embedded inside the spanning portion and the main layer, and respectively coupled to the first power finger and the second power finger. The ground wiring includes a first ground finger mounted on the main layer, a second ground finger mounted on the spanning portion, and a ground conductive trace embedded inside the spanning portion and the main layer, and respectively coupled to the first ground finger and the second ground finger.

In one embodiment of the present disclosure, a semiconductor package structure includes a main layer, at least one power wiring, at least one ground wiring, at least one power solder ball, at least one ground solder ball, at least one power wiring and at least one ground wiring, a semiconductor die, a power bonding wire, a ground bonding wire and an encapsulated body. The main layer is formed with a plurality of elongated slots therein, so that a power/ground zone of the main layer is matchingly formed between the elongated slots. The power wiring and the ground wiring are respectively embedded inside the power/ground zone of the main layer. The power solder ball and the ground solder ball are respectively mounted on a front surface of the main layer. The semiconductor die is mounted on a rear surface of the main layer being opposite to the front surface, and provided with at least one power contact pad and at least one ground contact pad respectively extended into the elongated slots. The power bonding wire is electrically connected to the power contact pad and the power wiring via one of the elongated slots. The ground bonding wire is electrically connected to the ground contact pad and the ground wiring via another of the elongated slots. The encapsulated body encloses the main layer and the semiconductor die together.

According to one or more embodiments of the present disclosure, in the semiconductor package structure, the semiconductor die fixedly covers the rear surface of the main layer and all of the elongated slots.

According to one or more embodiments of the present disclosure, the semiconductor package structure further includes at least one signal solder ball and at least one signal wiring. The signal solder ball is mounted on the front surface of the main layer. The signal wiring is embedded inside the main layer only. The semiconductor die is further provided with at least one signal contact pad extended within the elongated slots, and the signal contact pad is electrically connected to the signal wiring with a signal bonding wire via one of the elongated slots.

According to one or more embodiments of the present disclosure, in the semiconductor package structure, the power/ground zone in one of a linear shape and a cross shape.

According to one or more embodiments of the present disclosure, in the semiconductor package structure, the power/ground zone includes a first long portion and a second long portion which are orthogonal to each other. The power solder ball includes a plurality of power solder balls, one part of the power wirings extends into the first long portion through the second long portion, and another part of the power wirings extends into the first long portion without passing through the second long portion, the ground solder ball includes a plurality of ground solder balls, one part of the ground wirings extends into the first long portion through the second long portion, and another part of the ground wirings extends into the first long portion without passing through the second long portion.

According to one or more embodiments of the present disclosure, in the semiconductor package structure, one part of the encapsulated body covers the front surface of the main layer, the elongated slots and the power/ground zone, and another part of the encapsulated body covers the rear surface of the main layer and the semiconductor die.

According to one or more embodiments of the present disclosure, in the semiconductor package structure, the power/ground zone of the main layer is between long sides of the elongated slots or short sides of the elongated slots.

According to one or more embodiments of the present disclosure, in the semiconductor package structure, the power/ground zone of the main layer is provided without any signal wiring therein.

According to one or more embodiments of the present disclosure, in the semiconductor package structure, the power wiring includes a first power finger mounted on the front surface of the main layer, a second power finger mounted on the power/ground zone, and a power conductive trace embedded inside the power/ground zone, and respectively coupled to the first power finger and the second power finger. The ground wiring includes a first ground finger mounted on the front surface of the main layer, a second ground finger mounted on the power/ground zone, and a ground conductive trace embedded inside the power/ground zone, and respectively coupled to the first ground finger and the second ground finger.

According to one or more embodiments of the present disclosure, a method of manufacturing a semiconductor package structure includes several steps as follows. At least one power wiring and at least one ground wiring are formed to be embedded inside a substrate according to a layout pattern. A plurality of elongated slots are formed on the substrate to define a power/ground zone of the substrate between the elongated slots according to the layout pattern so that the power wiring and the ground wiring are intentionally embedded inside the power/ground zone. At least one power solder ball is mounted on the substrate to be electrically connected to the power wiring, and at least one ground solder ball on the substrate to be electrically connected to the ground wiring. A semiconductor die is attached on the substrate, so that at least one power contact pad and at least one ground contact pad of the semiconductor die are respectively extended into the elongated slots. The power wiring is electrically connected to the power contact pad with a power bonding wire. The ground wiring is electrically connected to the ground contact pad with a ground bonding wire. An encapsulated body is formed to enclose the substrate and the semiconductor die together.

Thus, through the construction of the embodiments above, since the power wiring and the ground wiring are deployed away from the signal wiring, the power wiring and the ground wiring will not be interfered by the signal wiring in the substrate, thereby, the speed and conduction performance of power and ground will not be affected and weakened, and the possibility of IR drop effect might be decreased in the semiconductor package structure.

The above description is merely used for illustrating the problems to be resolved, the technical methods for resolving the problems and their efficacies, etc. The specific details of the present disclosure will be explained in the embodiments below and related drawings.

### BRIEF DESCRIPTION OF THE DRAWINGS

The invention can be more fully understood by reading the following detailed description of the embodiment, with reference made to the accompanying drawings as follows:

FIG. 1 is a top view of a semiconductor package structure according to one embodiment of the present disclosure.

FIG. 2 is a cross-sectional view of the semiconductor package structure viewed along a line AA of FIG. 1.

FIG. 3 is a cross-sectional view of the semiconductor package structure viewed along a line BB of FIG. 1.

FIG. 4 is a top view of the substrate of FIG. 1.

FIG. 5 is a cross-sectional view of the semiconductor package structure viewed along a line CC of FIG. 1.

FIG. 6A to FIG. 6C are variety of main layers according to embodiments of the present disclosure.

FIG. 7 is a flow chart of a method of manufacturing a semiconductor package structure according to one embodiment of the present disclosure.

### DETAILED DESCRIPTION

Reference will now be made in detail to the present embodiments of the present disclosure, examples of which are illustrated in the accompanying drawings. Wherever possible, the same reference numbers are used in the drawings and the description to refer to the same or like parts. According to the embodiments, it will be apparent to those skilled in the art that various modifications and variations can be made to the structure of the present disclosure without departing from the scope or spirit of the present disclosure.

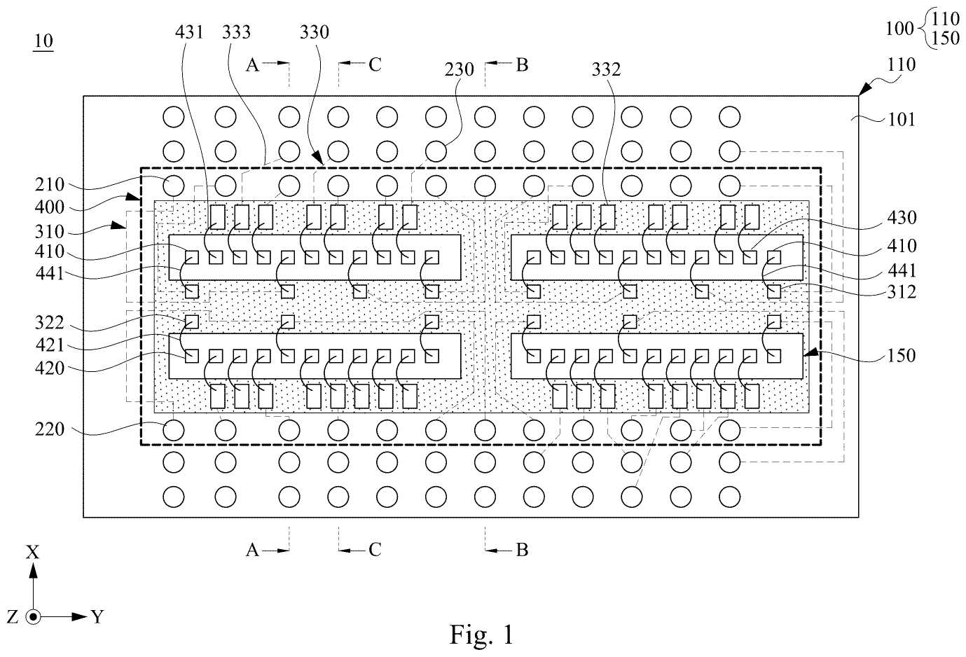

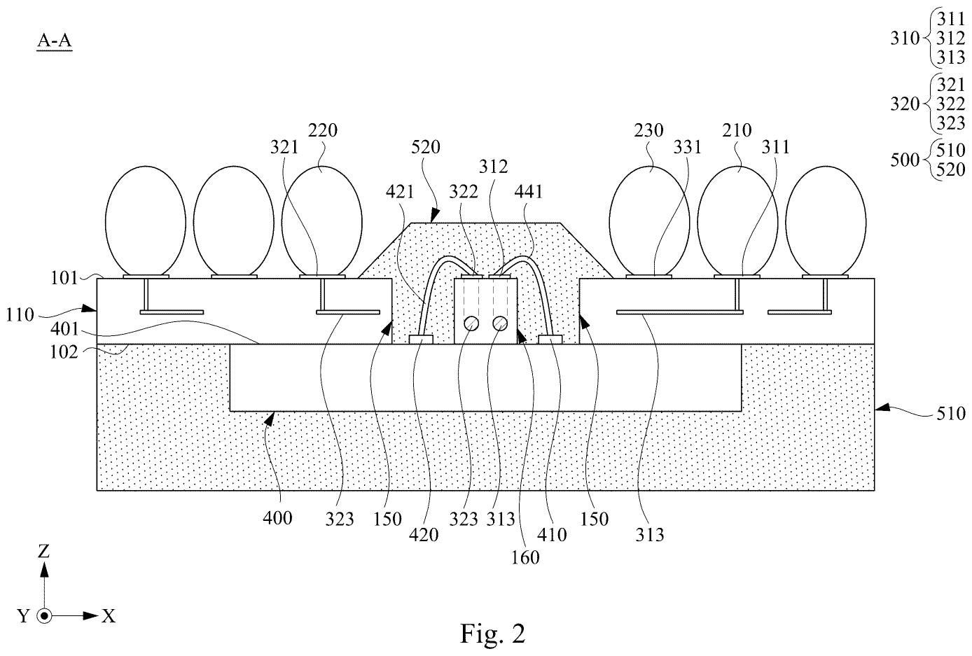

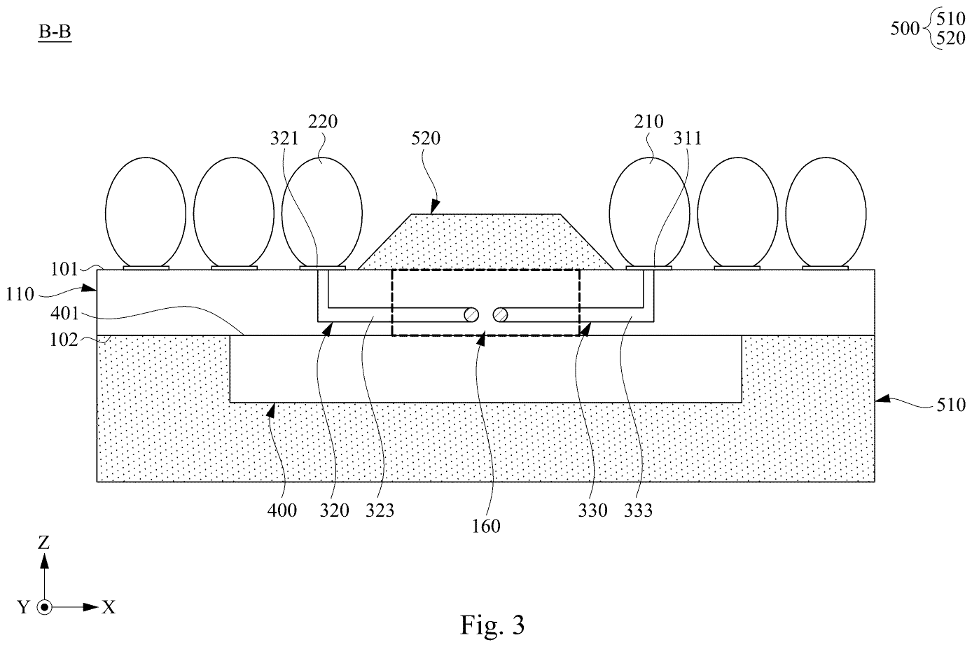

Reference is now made to FIG. 1 to FIG. 3, in which FIG. 1 is a top view of a semiconductor package structure 10 according to one embodiment of the present disclosure, and FIG. 2 is a cross-sectional view taken along a line A-A in FIG. 1. FIG. 3 is a cross-sectional view of the semiconductor package structure 10 viewed along a line BB of FIG. 1. As shown in FIG. 1 to FIG. 3, in the embodiment, the semiconductor package structure 10 includes a substrate 100, a semiconductor die 400 and an encapsulated body 500. The substrate 100 includes a main layer 110 and a plurality (e.g., four) of elongated slots 150 respectively formed thereon. The main layer 110 is provided with a front surface 101 and a rear surface 102 which are opposite to each other, and each of the elongated slots 150 penetrates through the main layer 110 along a vertical direction (e.g., Z-axis direction) to be connected to the front surface 101 and the rear surface 102 of the main layer 110.

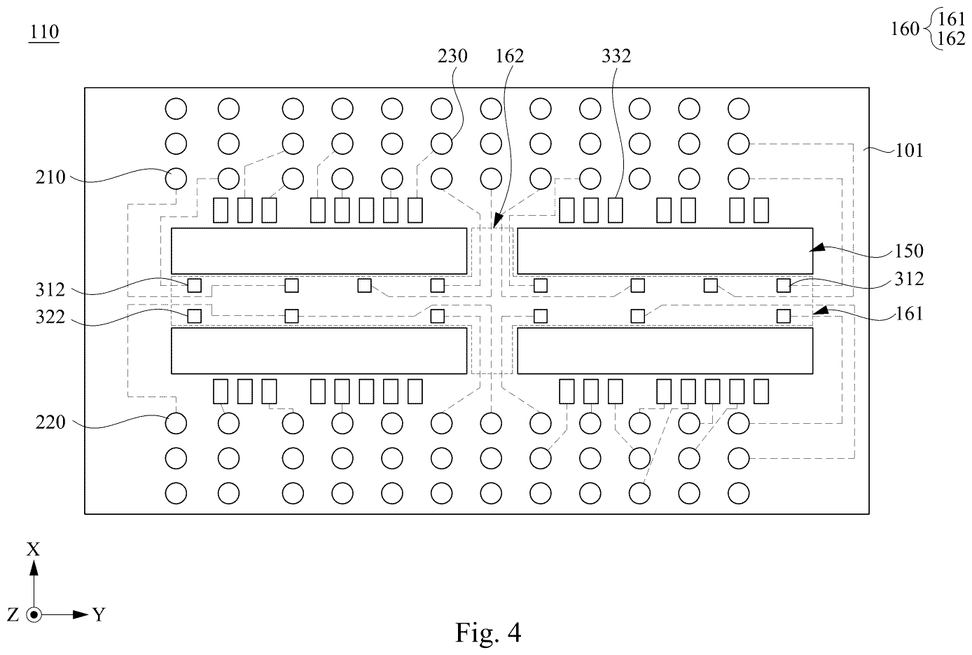

FIG. 4 is a top view of the substrate of FIG. 1. As shown in FIG. 1 and FIG. 4, in this embodiment, the elongated slots 150 are arranged on the main layer 110 in a 2×2 matrix manner so that a power/ground zone 160 of the main layer 110 is defined among the elongated slots 150. In the other word, these elongated slots 150 can be totally summed up as a single breach portion, and the power/ground zone 160 matchingly formed between those elongated slots 150 can be seemed as a spanning portion extending across the breach portion from the main layer 110. The power/ground zone 160 matchingly formed between the elongated slots 150 can be seemed as a spanning portion extending across the breach portion from the main layer 110. For example, the power/ground zone 160 (i.e., spanning portion) is in a cross shape, and connected to four edges of the breach portion, respectively. However, the disclosure is not limited to the shape of the power/ground zone 160.

The substrate 100 further includes a ball grid array (BGA) having a plurality of solder balls. The solder balls are mounted on the front surface 101 of the main layer 110, and spaced distributed on the front surface 101 of the main layer 110 along an X-Y plane direction. It is noted, the solder balls can be a plurality of power solder balls 210 for sending power signals, and a plurality of ground solder balls 220 for sending ground signals.

The substrate 100 further includes a plurality of power wirings 310 and a plurality of ground wirings 320. Those power wirings 310 and those ground wirings 320 are respectively embedded inside the main layer 110, and spaced distributed within the main layer 110 three-dimensionally. Each of the power wirings 310 is electrically connected to the semiconductor die 400 and one of the power solder balls 210 respectively for sending power signals to the semiconductor die 400 via this power solder ball 210. Each of the ground wirings 320 is electrically connected to the semiconductor die 400 and one of the ground solder balls 220 respectively for sending ground signals away from the semiconductor die 400 via this ground solder ball 220.

Specifically, each of the power wirings 310 is embedded inside the power/ground zone 160 (i.e., spanning portion) and the main layer 110. For example, in this embodiment, each of the power wirings 310 includes a first power finger 311, a second power finger 312 and a power conductive trace 313. The first power finger 311 is mounted on the front surface 101 of the main layer 110 for loading and conducting one of the power solder balls 210. The second power finger 312 is mounted on a front surface 101 of the power/ground zone 160 (i.e., spanning portion). The power conductive trace 313 is totally embedded inside the power/ground zone 160 (i.e., spanning portion) and the main layer 110, and directly coupled to the first power finger 311 and the second power finger 312, respectively.

Each of the ground wirings 320 is embedded inside the power/ground zone 160 (i.e., spanning portion) and the main layer 110. For example, in this embodiment, each of the ground wirings 320 includes a first ground finger 321, a second ground finger 322 and a ground conductive trace 323. The first ground finger 321 is mounted on the front surface 101 of the main layer 110. The second ground finger 322 is mounted on the front surface 101 of the power/ground zone 160 (i.e., spanning portion). The ground conductive trace 323 is totally embedded inside the power/ground zone 160 (i.e., spanning portion) and the main layer 110, and directly coupled to the first ground finger 321 and the ground finger, respectively.

The semiconductor die 400 is mounted on the substrate 100, and the semiconductor die 400 is mounted on the rear surface 102 of the substrate 100. Furthermore, the semiconductor die 400 directly attaches on the second surface of the substrate 100 by using an adhesive (not shown in figures). The semiconductor die 400 is provided with a plurality of power contact pads 410 and a plurality of ground contact pads 420 on the top surface 401 of the semiconductor die 400. For example, the semiconductor die 400 fixedly covers the rear surface 102 of the main layer 110 and all of the elongated slots 150 (i.e., breach portion), that is, the semiconductor die 400 fixedly covers the rear surface 102 of the main layer 110, the breach portion and the power/ground zone 160 (i.e., spanning portion).

The power contact pads 410 are spaced arranged on the top surface 401 of the semiconductor die 400, and extended into one of the elongated slots 150. Each of the power contact pads 410 is electrically connected to one of the power wirings 310 with a power bonding wire 441 via this elongated slot. That is, the power bonding wire 441 is connected to the second power finger 312 and the power contact pad 410, respectively.

The ground contact pads 420 are spaced arranged on the top surface 401 of the semiconductor die 400, and extended into another of the elongated slots 150, and the power/ground zone 160 (i.e., spanning portion) is interposed between the ground contact pads 420 and the power contact pads 410. Each of the ground contact pads 420 is electrically connected to one of the ground wiring 320 with a ground bonding wire 421 via another of the elongated slots 150. That is, the ground bonding wire 421 is connected to the second ground finger 322 and the ground contact pad 420, respectively.

The power/ground zone 160 (i.e., spanning portion) includes a first long portion 161 and a second long portion 162 which are orthogonal to each other. The power wirings 310 and the ground wirings 320 are embedded inside the first long portion 161 and the second long portion 162. The second power fingers 312 of the power wirings 310 and the second ground fingers of the ground wirings 320 are only arranged in the first long portion 161 rather than in the second long portion 162. Also, some of the power wirings 310 extend into the first long portion 161 through the second long portion 162, and the others extend into the first long portion 161 without passing through the second long portion 162. Some of the ground wirings 320 extend into the first long portion 161 through the second long portion 162, and the others extend into the first long portion 161 without passing through the second long portion 162.

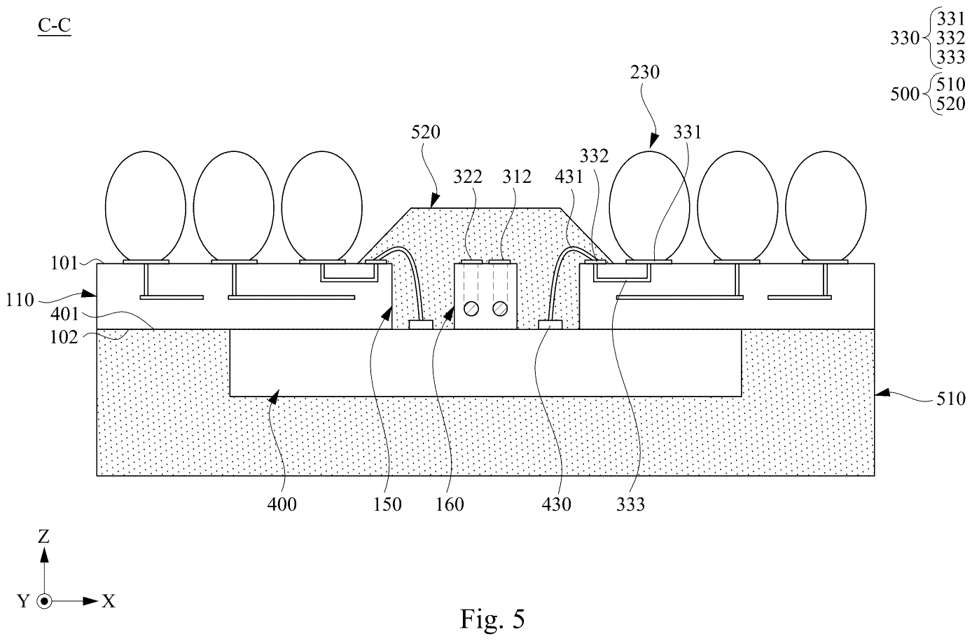

FIG. 5 is a cross-sectional view of the semiconductor package structure 10 viewed along a line CC of FIG. 1. As shown in FIG. 1 and FIG. 5, the substrate 100 further includes a plurality of signal wirings 330. Those signal wirings 330 are respectively embedded inside the main layer 110, and spaced distributed within the main layer 110 three-dimensionally. The abovementioned solder balls further includes a plurality of signal solder balls 230 respectively mounted on the front surface 101 of the main layer 110, and spaced distributed on the front surface 101 of the main layer 110 along an X-Y plane direction for sending working signals. Each of the signal wirings 330 is electrically connected to the semiconductor die 400 and one of the signal solder balls 230 respectively for exchanging the working signals between the semiconductor die 400 and the substrate 100 via this signal solder ball 230.

It is noted, those signal wirings 330 are only employed inside the main layer 110, rather than inside the power/ground zone 160 (i.e., spanning portion), that is, the power/ground zone 160 (i.e., spanning portion) is provided without any signal wiring 330 embedded therein.

For example, in this embodiment, each of the signal wirings 330 includes a first signal finger 331, a second signal finger 332 and a signal conductive trace 333. The first signal finger 331 is mounted on the front surface 101 of the main layer 110 for loading and conducting one of the signal solder balls 230. The second signal finger 332 is mounted on the front surface 101 of the main layer 110, and between the signal solder balls 230 and the power/ground zone 160 (i.e., spanning portion). The signal conductive trace 333 is totally embedded inside the main layer 110 only, and directly coupled to the first signal finger 331 and the signal finger, respectively. In this embodiment, some of the second signal fingers of the signal wirings 330 are arranged linearly along a long edge of the corresponding elongated slot. All of the elongated slots 150 are located between the second signal fingers of the signal wirings 330.

The semiconductor die 400 is further provided with a plurality of signal contact pads 430 which are arranged in two rows on the top surface 401 of the semiconductor die 400, and extended within the elongated slots 150. Each of the signal contact pads 430 is electrically connected to one of the signal wirings 330 with a signal bonding wire 431 via the corresponding elongated slot, that is, the signal bonding wire 431 is connected to the second signal finger 332 and the signal contact pad, respectively.

As shown in FIG. 2, the encapsulated body 500 encloses the substrate 100 and the semiconductor die 400 together. The encapsulated body 500 includes a first encapsulated member 510 and a second encapsulated member 520. Specifically, a resin is injected into the mold so as to form the first encapsulated member 510 on one side of the substrate 100 to enclose the semiconductor die 400, and the second encapsulated member 520 on the other side of the substrate 100 to be fully filled into all of the elongated slots 150 (i.e., breach portion) and excluded the power solder balls 210, the ground solder balls 220 and the signal solder balls 230 therefrom.

In this embodiment, the first encapsulated member 510 directly covers the front surface 101 of the main layer 110 and the power/ground zone 160 (i.e., spanning portion) to be fully filled all of the elongated slots 150 (i.e., breach portion) to wrap the power contact pads 410, the ground contact pads 420 and the signal contact pads 430 together. The second encapsulated member 520 directly covers the rear surface 102 of the main layer 110 and the semiconductor die 400 to completely wrap the semiconductor die 400 therein. However, the disclosure is not limited thereto.

In the above embodiment, the semiconductor package structure 10, for example, is implemented to a chipset in the form of multiple window ball grid array (MWBGA) package, and each of the elongated slots 150 can be a window of the multiple window ball grid array (MWBGA) package.

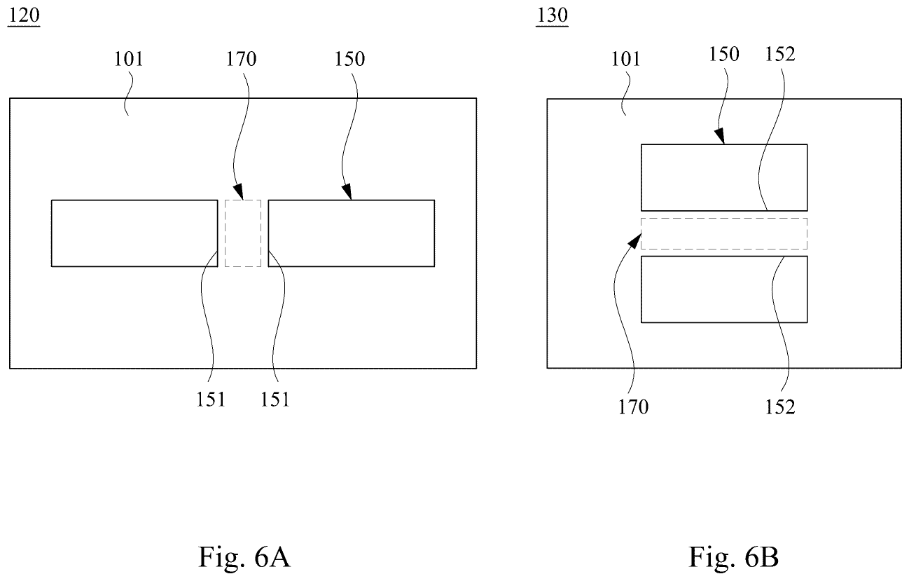

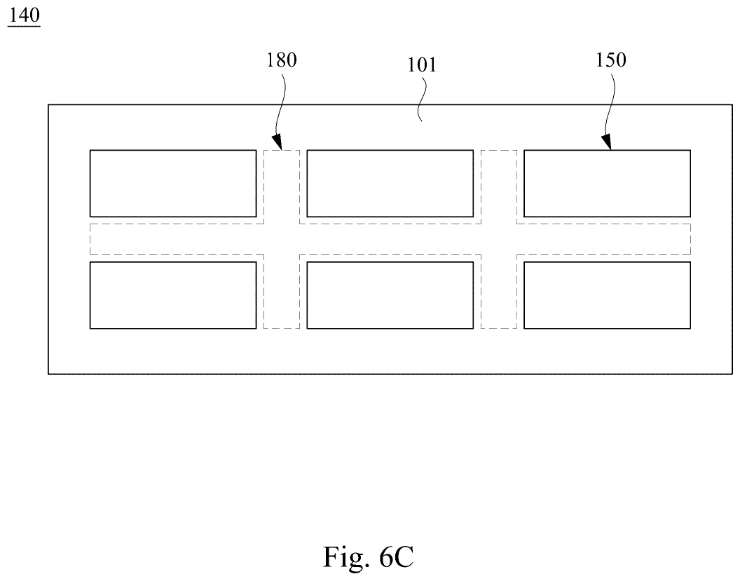

FIG. 6A to FIG. 6C are variety of main layers 120, 130, 140 according to embodiments of the present disclosure. As shown in FIG. 4 and FIG. 6A, a main layer 120 in FIG. 6A and the above embodiment of the main layer 110 in FIG. 4 are substantially the same, except that the elongated slots 150 are two in number, and the power/ground zone 170 (i.e., spanning portion) defined by the elongated slots 150 in this embodiment is in a linear shape.

Specifically, these elongated slots 150 are formed on the main layer 120. Each of the elongated slots 150 is in a rectangle shape having two opposite long sides 152 and two opposite short sides 151. Thus, the power/ground zone 170 (i.e., spanning portion) is defined by the closing short sides 151 of the elongated slots 150. However, the disclosure is not limited thereto.

In another embodiment, a main layer 130 in FIG. 6B and the above embodiment of the main layer 120 in FIG. 6A are substantially the same, except that, the power/ground zone 170 (i.e., spanning portion) of the main layer 130 in this embodiment is between two closing long sides 152 of the corresponding elongated slots 150. Thus, the power/ground zone 170 (i.e., spanning portion) is defined by the closing long sides 152 of the elongated slots 150.

In one another embodiment, as shown in FIG. 6C, a main layer 140 in FIG. 6C and the above embodiment of the main layer 110 in FIG. 4 are substantially the same, except that the power/ground zone 180 (i.e., spanning portion) in this embodiment is in a double-cross shape. However, the disclosure is not limited thereto. Specifically, six elongated slots 150 are arranged on the main layer 140 in a 2×3 array. Thus, the power/ground zone 180 (i.e., spanning portion) is defined by those elongated slots 150.

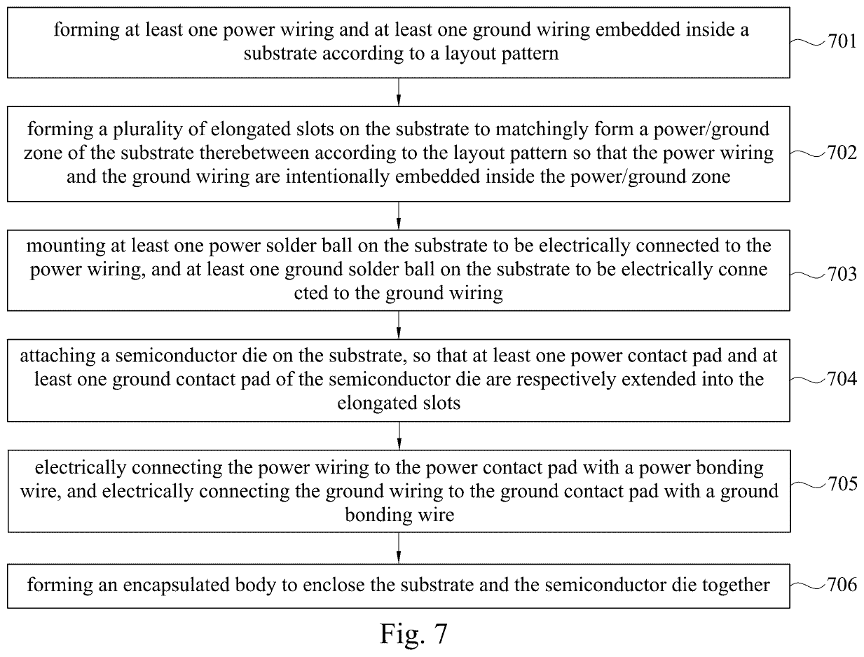

FIG. 7 is a flow chart of a method of manufacturing a semiconductor package structure according to one embodiment of the present disclosure. As shown in FIG. 7, the method of manufacturing a semiconductor package structure includes step 701 to step 706 as follows. In step 701, at least one power wiring and at least one ground wiring are formed to be embedded inside a substrate according to a layout pattern. In step 702, a plurality of elongated slots are formed on the substrate to matchingly form a power/ground zone of the substrate between the elongated slots according to the layout pattern so that the power wiring and the ground wiring are intentionally embedded inside the power/ground zone. In step 703, at least one power solder ball is mounted on the substrate to be electrically connected to the power wiring, and at least one ground solder ball on the substrate to be electrically connected to the ground wiring. In step 704, a semiconductor die is attached on the substrate, so that at least one power contact pad and at least one ground contact pad of the semiconductor die are respectively extended into the elongated slots. In step 705, the power wiring is electrically connected to the power contact pad with a power bonding wire, and the ground wiring is electrically connected to the ground contact pad with a ground bonding wire. In step 706, an encapsulated body is formed to enclose the substrate and the semiconductor die together.

More specifically, in step 701, at least one signal wiring is further formed to be embedded inside the main layer of substrate only according to the layout pattern. Thus, the power wiring and the ground wiring will not be interfered by the signal wiring in the substrate.

More specifically, in step 703, at least one signal solder ball is mounted on the substrate to be electrically connected to the signal wiring.

More specifically, before step 706, the signal wiring is electrically connected to at least one signal contact pad of the semiconductor die with a signal bonding wire via one of the elongated slots.

Should be noted, the fingers described above can be, for example copper pads respectively coated on the surface of the main layer 110; the conductive traces described above can be, for example copper line coated inside the main layer 110 respectively; contact pad described above can be, for example copper pads respectively coated on the top surface 401 of the semiconductor die 400; and the bonding wires described above can be for example, gold wire made by a gold wire bonder.

Thus, through the construction of the embodiments above, since the power wiring and the ground wiring are deployed away from the signal wiring, the power wiring and the ground wiring will not be interfered by the signal wiring in the substrate, thereby, the speed and conduction performance of power and ground will not be affected and weakened, and the possibility of IR drop effect might be decreased in the semiconductor package structure.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A semiconductor package structure, comprising:
a substrate comprising a main layer, a breach portion penetrated through the main layer, a spanning portion extending across the breach portion from the main layer, at least one power solder ball mounted on the main layer, at least one ground solder ball mounted on the main layer, at least one power wiring embedded inside the spanning portion and the main layer, and at least one ground wiring embedded inside the spanning portion and the main layer;
a semiconductor die mounted on the substrate, and provided with at least one power contact pad and at least one ground contact pad extended into the breach portion, respectively, wherein the power contact pad is electrically connected to the power wiring with a power bonding wire via the breach portion, and the ground contact pad electrically connected to the ground wiring with a ground bonding wire via the breach portion; and
an encapsulated body enclosing the substrate and the semiconductor die together.

2. The semiconductor package structure of claim 1, wherein the main layer is provided with a front surface and a rear surface which are opposite to each other, the power solder ball and the ground solder ball are located on the front surface of the main layer, and the semiconductor die fixedly covers the rear surface of the main layer, the breach portion and the spanning portion.

3. The semiconductor package structure of claim 1, wherein the substrate comprises at least one signal solder ball mounted on the main layer, and at least one signal wiring embedded inside the main layer only; and
the semiconductor die is further provided with at least one signal contact pad extended within the breach portion, and the signal contact pad is electrically connected to the signal wiring with a signal bonding wire via the breach portion.

4. The semiconductor package structure of claim 1, wherein the spanning portion is connected to opposite edges of the breach portion, respectively.

5. The semiconductor package structure of claim 1, wherein the spanning portion is in one of a linear shape and a cross shape.

6. The semiconductor package structure of claim 1, wherein the spanning portion comprises a first long portion and a second long portion which are orthogonal to each other,
wherein the at least one power solder ball comprises a plurality of power solder balls, one part of the power wirings extends into the first long portion through the second long portion, and another part of the power wirings extends into the first long portion without passing through the second long portion, the at least one ground solder ball comprises a plurality of ground solder balls, one part of the ground wirings extends into the first long portion through the second long portion, and another part of the ground wirings extends into the first long portion without passing through the second long portion.

7. The semiconductor package structure of claim 1, wherein one part of the encapsulated body covers a front surface of the main layer, the breach portion and the spanning portion, and another part of the encapsulated body covers a rear surface of the main layer and the semiconductor die.

8. The semiconductor package structure of claim 1, wherein the spanning portion separates the breach portion into at least two windows, and the power contact pad and the ground contact pad are respectively extended within the windows.

9. The semiconductor package structure of claim 1, wherein the spanning portion is provided without any signal wiring embedded therein.

10. The semiconductor package structure of claim 1, wherein the power wiring comprises a first power finger mounted on the main layer, a second power finger mounted on the spanning portion, and a power conductive trace embedded inside the spanning portion and the main layer, and respectively coupled to the first power finger and the second power finger; and
the ground wiring comprises a first ground finger mounted on the main layer, a second ground finger mounted on the spanning portion, and a ground conductive trace embedded inside the spanning portion and the main layer, and respectively coupled to the first ground finger and the second ground finger.

11. A semiconductor package structure, comprising:
a main layer formed with a plurality of elongated slots therein, so that a power/ground zone of the main layer is matchingly formed between the elongated slots;
at least one power wiring and at least one ground wiring respectively embedded inside the power/ground zone of the main layer;
at least one power solder ball and at least one ground solder ball respectively mounted on a front surface of the main layer;
a semiconductor die mounted on a rear surface of the main layer being opposite to the front surface, and provided with at least one power contact pad and at least one ground contact pad respectively extended into the elongated slots;
a power bonding wire electrically connected to the power contact pad and the power wiring via one of the elongated slots;
a ground bonding wire electrically connected to the ground contact pad and the ground wiring via another of the elongated slots; and
an encapsulated body enclosing the main layer and the semiconductor die together.

12. The semiconductor package structure of claim 11, wherein the semiconductor die fixedly covers the rear surface of the main layer and all of the elongated slots.

13. The semiconductor package structure of claim 11, further comprising:
at least one signal solder ball mounted on the front surface of the main layer; and
at least one signal wiring embedded inside the main layer only, wherein the semiconductor die is further provided with at least one signal contact pad extended within the elongated slots, and the signal contact pad is electrically connected to the signal wiring with a signal bonding wire via one of the elongated slots.

14. The semiconductor package structure of claim 11, wherein the power/ground zone in one of a linear shape and a cross shape.

15. The semiconductor package structure of claim 11, wherein the power/ground zone comprises a first long portion and a second long portion which are orthogonal to each other,
wherein the at least one power solder ball comprises a plurality of power solder balls, one part of the power wirings extends into the first long portion through the second long portion, and another part of the power wirings extends into the first long portion without passing through the second long portion, the at least one ground solder ball comprises a plurality of ground solder balls, one part of the ground wirings extends into the first long portion through the second long portion, and another part of the ground wirings extends into the first long portion without passing through the second long portion.

16. The semiconductor package structure of claim 11, wherein one part of the encapsulated body covers the front surface of the main layer, the elongated slots and the power/ground zone, and another part of the encapsulated body covers the rear surface of the main layer and the semiconductor die.

17. The semiconductor package structure of claim 11, wherein the power/ground zone of the main layer is between long sides of the elongated slots or short sides of the elongated slots.

18. The semiconductor package structure of claim 11, wherein the power/ground zone of the main layer is provided without any signal wiring therein.

19. The semiconductor package structure of claim 11, wherein the power wiring comprises a first power finger mounted on the front surface of the main layer, a second power finger mounted on the power/ground zone, and a power conductive trace embedded inside the power/ground zone, and respectively coupled to the first power finger and the second power finger; and
the ground wiring comprises a first ground finger mounted on the front surface of the main layer, a second ground finger mounted on the power/ground zone, and a ground conductive trace embedded inside the power/ground zone, and respectively coupled to the first ground finger and the second ground finger.

20. A manufacturing method of a semiconductor package structure, comprising:
forming at least one power wiring and at least one ground wiring embedded inside a substrate according to a layout pattern;
forming a plurality of elongated slots on the substrate to define a power/ground zone of the substrate between the elongated slots according to the layout pattern so that the power wiring and the ground wiring are intentionally embedded inside the power/ground zone;
mounting at least one power solder ball on the substrate to be electrically connected to the power wiring, and at least one ground solder ball on the substrate to be electrically connected to the ground wiring;
attaching a semiconductor die on the substrate, so that at least one power contact pad and at least one ground contact pad of the semiconductor die are respectively extended into the elongated slots;
electrically connecting the power wiring to the power contact pad with a power bonding wire;
electrically connecting the ground wiring to the ground contact pad with a ground bonding wire; and
forming an encapsulated body to enclose the substrate and the semiconductor die together.
